(19) United States
(12) Patent Application Publication
(10) Pub. No.: US 2024/0234304 A1
(43) Pub. Date: Jul. 11, 2024

(54) CHIP PACKAGE WITH CORE EMBEDDED CHIPLET

(71) Applicants: Advanced Micro Devices, Inc., Santa Clara, CA (US); ATI Technologies ULC, Thornhill (CA)

(72) Inventors: Deepak Vasant KULKARNI, Austin, TX (US); Samuel NAFFZIGER, Fort Collins, CO (US); Raja SWAMINATHAN, Austin, TX (US); Matthew STRAAYER, Boxborough, MA (US); Justin Michael BURKHART, Boxborough, MA (US); Sri Ranga Sai BOYAPATI, Austin, TX (US); Hemanth Kumar DHAVALESWARAPU, Austin, TX (US); Alexander Helmut PFEIFFENBERGER, Toronto (CA); Manjunath D. HARITSA, Santa Clara, CA (US)

(21) Appl. No.: 18/402,688

(22) Filed: Jan. 2, 2024

Related U.S. Application Data
(60) Provisional application No. 63/437,585, filed on Jan. 6, 2023.

(51) Int. Cl. H01L 23/522; H01L 23/00; H01L 23/498; H01L 25/065

(52) U.S. Cl. CPC H01L 23/5227; H01L 23/49816; H01L 23/49822; H01L 24/13; H01L 24/29; H01L 25/0652; H01L 2224/13025; H01L 2224/13147; H01L 2224/29009; H01L 2224/29025; H01L 2924/1206; H01L 2924/1427; H01L 2924/1431; H01L 2924/15311

(57) ABSTRACT

Chip packages are described herein that includes chiplets embedded in a core of a substrate of the chip package, such as a package substrate or an interposer. In one example, the chiplet includes voltage regulation circuitry that is coupled through a substrate core embedded inductor to an integrated circuit (IC) die mounted to the substrate.

### CROSS-REFERENCE TO RELATED APPLICATIONS

This application claims priority to the U.S. Provisional Patent Application Ser. No. 63/437,585 filed Jan. 6, 2023 of which is incorporated herein by reference in its entirety.

### TECHNICAL FIELD

Embodiments of the present invention generally relate to a chip package having a chiplet embedded in a core of a substrate, and in particular, to a chip package having voltage regulator chiplet embedded in a core of a substrate of the chip package, such as a package substrate or an interposer.

### BACKGROUND

Electronic devices, such as tablets, computers, copiers, digital cameras, smart phones, control systems, automated teller machines, data centers, artificial intelligence system, and machine learning systems among others, often employ electronic components which leverage chip package assemblies for increased functionality and higher component density. Conventional chip packaging schemes often utilize a package substrate, often in conjunction with a through-silicon-via (TSV) interposer substrate, to enable a plurality of integrated circuit (IC) dies to be mounted to a single package substrate. The IC dies are mounted to a top side (i.e., top surface) of the package substrate while a bottom side (i.e., bottom surface) of the package substrate is mounted to a printed circuit board (PCB). The IC dies may include memory, logic or other IC devices.

Chip packages, particularly those used in AI/ML and server applications, strive to include integrated voltage regulator systems. Power delivery through voltage regulators within a chip package often requires multiple voltage regulators to support each power rail, which significantly increases the cost, and also requires a significantly higher number of package pins in order to provide power at a input voltage of ˜1V.

To improve the performance of voltage regulators, some chip packages incorporate voltage regulators (power field effect transistors (FETs)) as part of the system on a chip (SOC) and place inductors in the core region of the package substrate. This solution has lower efficiency because of the IR drop connecting between the SOC and the embedded inductor, and the return path from inductor to SoC. Undesirably, this solution also requires custom SoC development for each product since the power FETs are part of the SOC design.

Other chip package place inductors or voltage regulator chiplets on the backside of the package or on the backside of the printed circuit board (PCB). Such solutions grow the package footprint and undesirably reduce the number of available package pins. Placing inductors or voltage regulator chiplets on the backside of the package or PCB also present heat dissipation challenges which requires custom backside cooling solutions.

Therefore, a need exists for a chip package with an improved voltage regular power delivery design.

### SUMMARY

Chip packages are described herein that includes chiplets embedded in a core of a substrate of the chip package, such as a package substrate or an interposer. In one example, the chiplet includes voltage regulation circuitry that is coupled through a substrate core embedded inductor to an integrated circuit (IC) die mounted to the substrate.

In one example, a chip package is provided that includes an integrated circuit (IC) die having functional circuitry, a substrate, and a chiplet. The IC die is mounted on the substrate. The substrate includes a core sandwiched between upper and lower build-up layers. The core includes at least a first cavity, a plurality of signal transmission vias, a plurality of ground, and a plurality of ground and power routing vias. The upper build-up layer is disposed on the core between the core and IC die. The upper build-up layer includes routing coupling the inductor routing vias, the signal transmission vias, and the ground and power routing vias to the functional circuitry of the IC die. The lower build-up layer is disposed a side of the core opposite the upper build-up layer. The lower build-up layer includes routing coupled to the functional circuitry of the IC die through the vias of the core and the routing of upper build-up layer. The chiplet is disposed in a first cavity formed the core. The chiplet coupled to the functional circuitry of the IC die through upper build-up layer.

In some examples, the chiplet includes voltage regulator circuitry.

In some examples, the voltage regulator circuitry of the chiplet is coupled to an inductor disposed in the substrate.

The inductor may be fabricated from magnetic material surrounding a conductor.

The chiplet may include a backside metal layer.

The backside metal layer may be connected to thermal vias that conduct heat from the chiplet to one of the IC die or a stiffener connected to a lid that covers the IC die.

The chiplet and inductor may reside in the same or different cavities formed in the core of the substrate.

In another example, a chip package is provided that includes an integrated circuit (IC) die having functional circuitry, a substrate and a chiplet. The IC die is mounted on the substrate. The substrate includes a core, an upper build-up layer, and a lower build-up layer. The core has one or more cavities, a plurality of signal transmission vias, a plurality of ground, and a plurality of ground and power routing vias. The upper build-up layer is disposed on the core between the core and IC die. The upper build-up layer includes routing coupling the inductor routing vias, the signal transmission vias, and the ground and power routing vias to the functional circuitry of the IC die. The lower build-up layer is disposed a side of the core opposite the upper build-up layer. The lower build-up layer includes routing coupled to the functional circuitry of the IC die through the vias of the core and the routing of upper build-up layer. The chiplet is disposed in the one or more cavities formed the core. The chiplet has voltage regulating circuitry coupled to the functional circuitry of the IC die through upper build-up layer. The inductor is also disposed in the one or more cavities formed the core. The inductor has an input and an output. The input of the inductor is coupled to an outlet of the voltage regulator circuitry while the output of the inductor is coupled to the functional circuitry of the IC die.

In yet another example, a method for fabricating a chip package is provided. The method includes securing a chiplet and an inductor in a cavity formed in a substrate; forming build-up layers on the substrate over the chiplet and the inductor, the build-up layers including routing electrically coupled to the chiplet and the inductor; and mounting an integrated circuit (IC) die on the build-up layers, the IC die including functional circuitry coupled by the routing of the build-up layers to the chiplet and the inductor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of one example of chip package having a chiplet disposed in a core of a substrate.

FIG. 2 is a schematic sectional view of another example of chip package having a chiplet disposed in a core of a substrate.

FIGS. 3A-31 depict the substrate that can be used the chip package of FIG. 1 during different stages of fabrication.

FIG. 4 is a block diagram of a method for fabricating a chip package.

FIGS. 5A-5F depict a magnetic inductor that can be used the chip packages of FIGS. 1-2 during different stages of fabrication.

FIG. 6 is a block diagram of a method for fabricating an inductor.

FIGS. 7A-7D depict a substrate having a magnetic inductor that can be used the chip packages of FIGS. 1-2 during different stages of fabrication.

FIG. 8 is a block diagram of a method for fabricating substrate having a magnetic inductor.

FIGS. 9A-9D depict another substrate having a magnetic inductor that can be used the chip packages of FIGS. 1-2 during different stages of fabrication.

FIG. 10 is a block diagram of a method for fabricating substrate having a magnetic inductor.

To facilitate understanding, identical reference numerals have been used, where possible, to designate identical elements that are common to the figures. It is contemplated that elements of one embodiment may be beneficially incorporated in other embodiments.

### DETAILED DESCRIPTION

A chip package and method for fabricating the same are provided that includes chiplet embedded in a core of a substrate of the chip package, such as a package substrate or an interposer. The embedded chiplet may include voltage regular circuitry that is routed through an accompanying inductor prior to connecting to an IC die of the chip package. The voltage regular circuitry include power routing field effect transistors (FETs). The accompanying inductor may also be embedded in the core of the substrate. The accompanying inductor may be an air core inductor, a magnetic inductor, or other suitable inductor.

The integrated voltage regulator solution described herein has various different components that most or all of which are embedded in the substrate core of the package. The embedded components include at least the inductors, and the voltage regulator (VR) chiplet. Capacitors of the integrated voltage regulator solution may also be embedded in the substrate core of the package, or alternatively be surface mounted nearby within the chip package or the PCB to which the chip package is mounted. The components are interspersed in the substrate core to optimize power delivery to the chips attached on to the substrate. By having multiple VR chiplets and inductors, the heat dissipation is managed to avoid hot spots. A novel multi-layer core architecture is used to optimize the embedding process and incorporate silicon chiplets in a thick core package. The thickness of the multilayer core is tuned to improve manufacturability of the embedding process, while still meeting the overall package thermo-mechanical warpage requirements. The use of the multi-layer core architecture provides short lateral connections between the inductors and the VR chiplets. In one example, the inductors are fabricated using magnetic materials to improve efficiency of the voltage regulator and maximize current density.

In some embodiments, magnetic material is embedded in the substrate core after inductor fabrication, which avoids leaching of the magnetic material. For example, the inductor may be fabricated using pre-cured magnetic blocks, through which routing are formed, then installed as a finished inductor into a cavity formed in the substrate.

In some embodiments, a novel backside thermal via solution is provided to improve heat conduction from the embedded VR chiplets. For example, a backside metal layer is deposited in the VR chiplets, and after embedding the VR chiplets in the core of the substrate, thermal vias are formed in the backside metal layer through the upper build-up layer of the substrate to allow heat generated by the VR chiplets to reach the upper surface of the substrate. From the upper surface of the substrate, the heat can this be dissipated through IC die and/or thought the stiffener to the lid of the package substrate. For improved heat conduction, the stiffener may be integrated into the lid.

In some embodiments, the VR chiplet and the inductor are disposed side by side in the same cavity of the substrate core. The resulting close proximity of the VR chiplet and the inductor beneficially provides a very short lateral path between the VR chiplet and the inductor, which improves performance.

The multi-layer core and embedding technology enables silicon components to be embedded in a thick core package, which provides for high inductance while meeting package thermo-mechanical warpage requirements.

Some additional benefits include one or more of: allowing high power (750-1000 W) delivery while maintaining package foot print; reducing the number of on-board voltage regulators, which reduces the overall cost of graphics cards; improving overall power delivery efficiency and product performance by moving the power delivery components closer to the IC dies within the chip package; enabling a modular chiplet design where the number and location of the VR chiplets can be optimized for each product without requiring a new SoC tape out; enabling embedding of silicon components, such as VR chiplets, inductors, silicon capacitors, by using a multi-layer core architecture where the inner core thickness is tuned to match the thickness of the embedded components; enabling efficient heat dissipation by incorporating thermal vias on the backside of the VR chiplets; enabling improved performance by the use of short lateral connection between the inductor and the VR chiplet using the multi-layer core architecture; improving the efficiency of the power delivery solution through the use of embedded magnetic material inductors in the core of the substrate; and increasing current density through the use of high inductance magnetic inductors.

In some examples, improved efficiency of the voltage regulator is enabled by optimally placing the VR chiplet and inductor right below the IC die within the chip package. Package size growth that comes from other solutions, such as on-board VR or back-side VR, is substantially prevented. The modular solution described herein allows for the same VR chiplet to be used on multiple products, thus avoiding a need for custom SOC tape outs. Additionally, the use of pre-fabricated magnetic slabs improve inductance and efficiency, and also mitigates the risk of contaminating the substrate manufacturing line from leaching of uncured magnetic material.

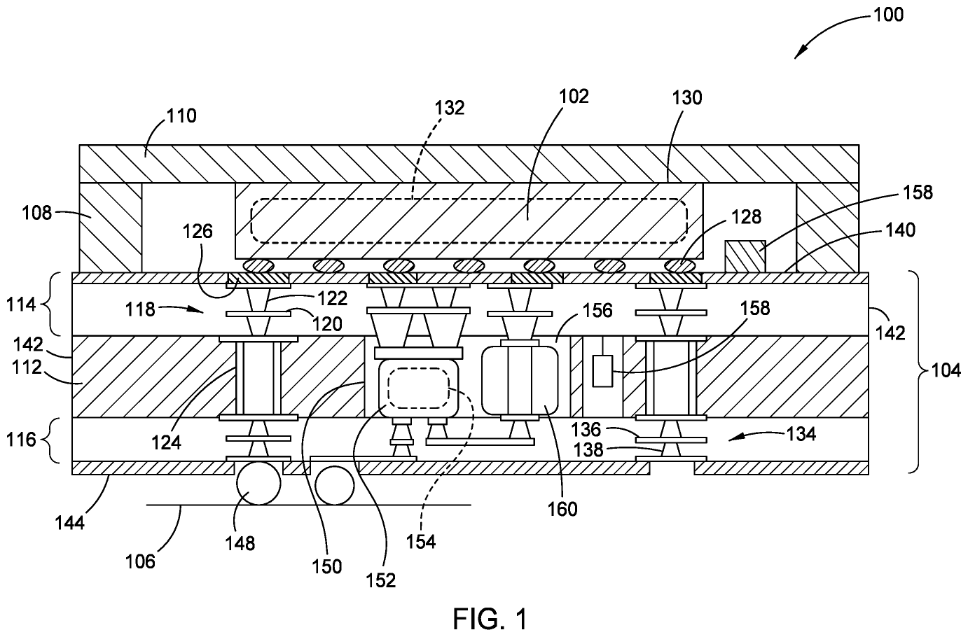

Turning now to FIG. 1, a chip package 100 is illustrated having at least one IC die 102 mounted on a substrate 104. The substrate 104 illustrated in FIG. 1 is a package substrate 104. However, the substrate 104 may alternatively be an interposer which is then mounted to a package substrate. Although only one IC die 102 is shown in FIG. 1, the number of IC dies 102 may range from one to as many as can be fit within the chip package 100. The IC die 102 may be a programmable logic device, such as field programmable gate array (FPGA), memory device, optical device, a logic device, processor, math engine, or other IC logic structures. Optical devices include photo-detectors, lasers, optical sources, and the like. In the embodiment depicted in FIG. 1, the IC die 102 is mounted to a top surface 140 of the substrate 104 by solder connections that enable communication between the IC die 102 and a printed circuit board (PCB) 106 after the chip package 100 is mounted within an electronic device (not shown).

The chip package 100 additionally includes a stiffener 108 and a lid 110. The lid 110 is disposed over a top surface 130 of the IC die 102. The stiffener 108 is coupled to the substrate 104 and circumscribes the IC die 102. The stiffener 108 can extend to peripheral edges 142 of the substrate 104 to provide mechanical support which helps prevent the chip package 100 from bowing and warpage. The stiffener 108 may be a single layer structure or a multi-layer structure. The stiffener 108 may also be part of the lid 110. To promote heat transfer to the lid 110 from the IC die 102 and other components of the chip package 100, the lid 110 and stiffener 108 may be fabricated from a thermally conductive material, such as copper, aluminum, copper-clad aluminum, nickel-plated copper or aluminum, among other suitable materials.

The substrate 104 generally includes a core 112 sandwiched between an upper build-up layer 114 and a lower build-up layer 116. The core 112 is generally fabricated from silicon or other rigid dielectric material. In one example, the core 112 is fabricated from an inorganic material. The core 112 includes conductive vias 124 for transferring power, ground and data signals between the substrate 104 and the IC die 102.

The upper build-up layer 114 includes pattern routings 118 formed from a plurality of metal layers that are separated by dielectric layers. The pattern routings 118 generally include conductive lines 120 formed from the metal layers that are connected by conductive vias 122. The routings 118 in the upper build-up layer 114 generally couple the vias 124 formed in the core 112 with exposed pads 126 formed on the top surface 140 of the substrate 104. The exposed pads 126 are connected by solder balls 128 or other suitable connection to IC die 102 such that the functional circuitry 132 residing the IC die 102 can receive power, ground and data signals through the substrate 104.

The lower build-up layer 116 is generally fabricated the same as the upper build-up layer 114. Routings 134 in the lower build-up layer 116 generally couple the vias 124 formed in the core 112 with exposed pads 146 formed on the bottom surface 144 of the substrate 104. The exposed pads 146 are connected by solder balls 148 or other suitable connection to the PCB 106 such that the functional circuitry 132 of the IC die 102 can communicate the circuitry of the PCB 106 through the substrate 104, i.e., through the circuitry of the substrate 104 formed from the routings 118, 134 of the upper and lower build-up layers 114, 116 and the vias 124 formed in the core 112.

The core 112 of the substrate 104 has one or more cavities 150 in which one or more chiplets 152 are embedded. The chiplet 152 is configured to provide a predefined functionality utilized by the IC die 102. In the example depicted in FIG. 1, the chiplet 152 has integrated voltage regulator circuitry 154. The voltage regular circuitry 154 includes power routing field effect transistors (power FETs). The integrated voltage regulator (IVR) chiplet 152 is preformed and installed in the cavity 150 formed in the core 112 of the substrate 104. The IVR chiplet 152 is connected through routings 134 of the lower build-up layer 116 to Vin provided by the PCB 106. The output of the IVR chiplet 152 is connected to an input of an inductor 160. The output of the inductor 160 is connected through the routings 118 of the upper build-up layer 114 to the functional circuitry 132 of the IC die 102. The inductor 160 may be an air core inductor formed in the substrate 104, or a preformed inductor disposed in a cavity of the core 112 of the substrate 104. In one example, the inductor 160 is fabricated from a preformed magnetic material.

A dielectric filler 156 fills the one or more cavities 150 holding the inductors 160 and chiplets 152. The dielectric filler 156 may be an epoxy or other suitable potting compound. The inductor 160 and connected IVR chiplet 152 may reside in the same or different cavities 150. In the example depicted in FIG. 1, the inductor 160 and connected IVR chiplet 152 reside in a common cavity 150 located directly below the IC die 102 to minimize routing lengths and improve performance.

A capacitor 158 is also coupled to the routing extending between the output of the inductor and the IC die 102. The capacitor 158 may be located in a cavity formed in the core 112 of the substrate 104, surface mounted to the exterior of the substrate 104, or mounted or formed in another location of the chip package 100. In FIG. 1, the capacitor 158 is shown in both alternative locations, that is, within the core 112 of the substrate 104 and surface mounted to the top surface 140 of the substrate 104.

The IVR chiplet includes a backside material layer. The backside material layer is connected to electrically floating routings formed in the upper build-up layer 114 that functions as thermal vias. Thermal vias efficiently transfer heat from the backside material layer to the silicon of the IC die 102, through which heat may pass to the lid 110, such cooling the IVR chiplet.

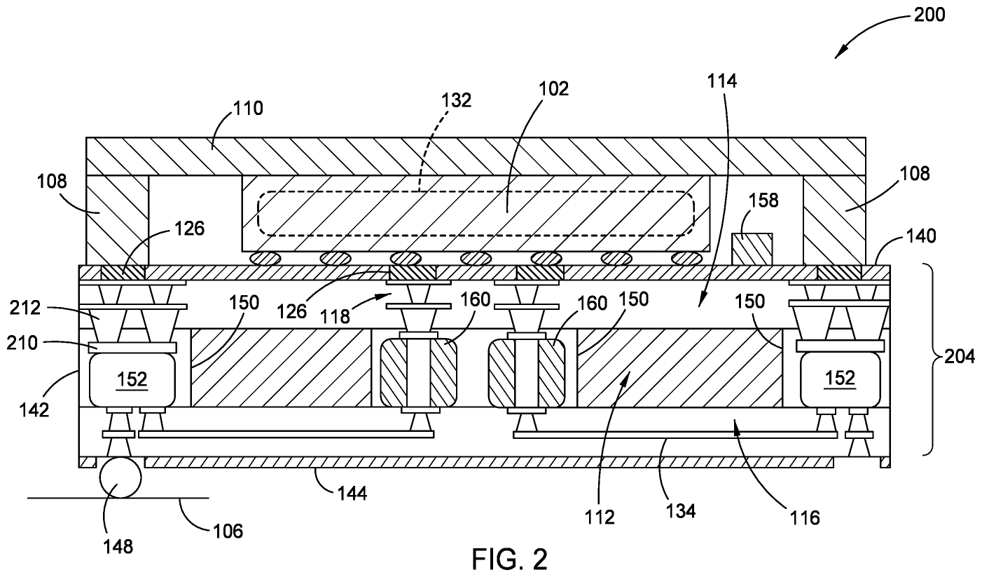

FIG. 2 is another example of a chip package 200 is illustrated having at least one IC die 102 mounted on a substrate 204, the substrate 204 having a core embedded chiplet 152. The chip package 200 of FIG. 2 is constructed essentially the same as the chip package 100 of FIG. 1, except that the IVR chiplet 152 is disposed laterally outward of the IC die 102. The inductor 160 coupled to the IVR chiplet 152 may optionally be disposed in the same cavity 150 as the IVR chiplet 152, or as illustrated in FIG. 2, the inductor 160 may be disposed directly below the IC die 102. Although the capacitor 158 is not shown in FIG. 2, it is to be understood that the capacitor 158 is connected to the output of the inductor 160 of FIG. 2 in any of the manners described with reference to FIG. 1.

Continuing to refer to FIG. 2, the IVR chiplet 152 is located below the stiffener 108, and in one example is directly below the stiffener 108 well outward of the IC die 102. The IVR chiplet 152 includes a backside material layer 210. Electrically floating routings 212 are formed in the upper build-up layer 114 connect to the backside material layer 210 disposed on the IVR chip 152. The electrically floating routings 212 extend upward through the upper build-up layer 114 to the stiffener 108. Thus, the electrically floating routings 212 provide a conductive heat transfer path from the backside material layer 210 disposed on the IVR chip 152 directly to the lid 110 through the stiffener 108. This improves thermal regulation of the IVR chip 152, although in some examples the performance may not be as robust as the configuration of FIG. 1.

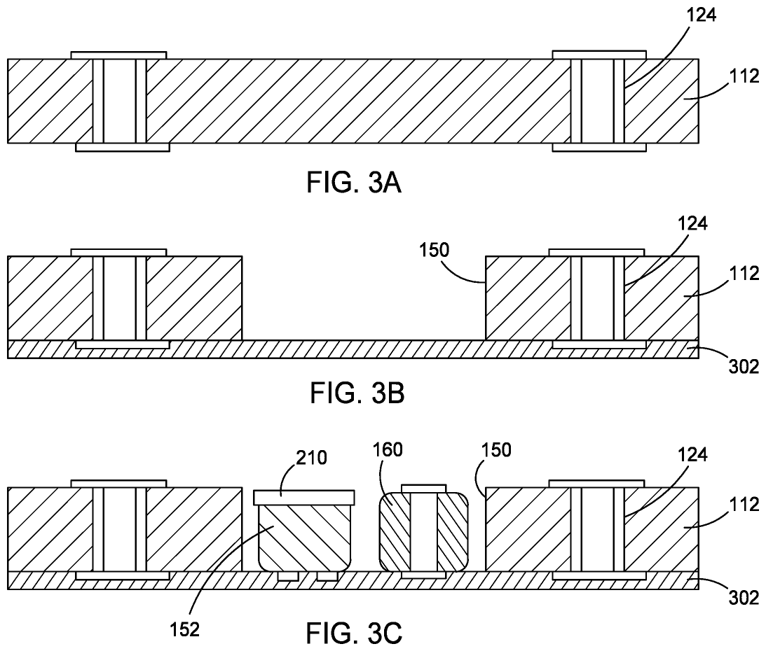

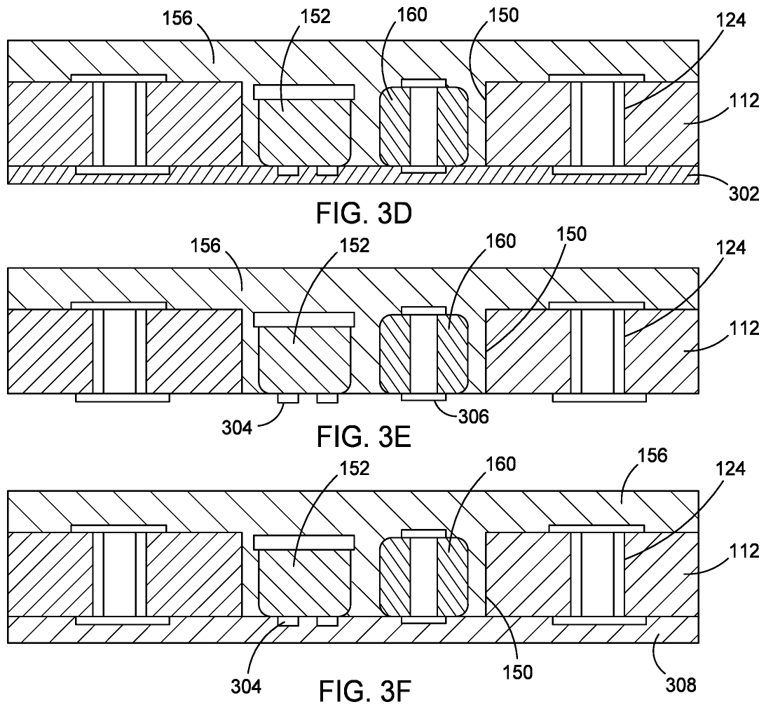

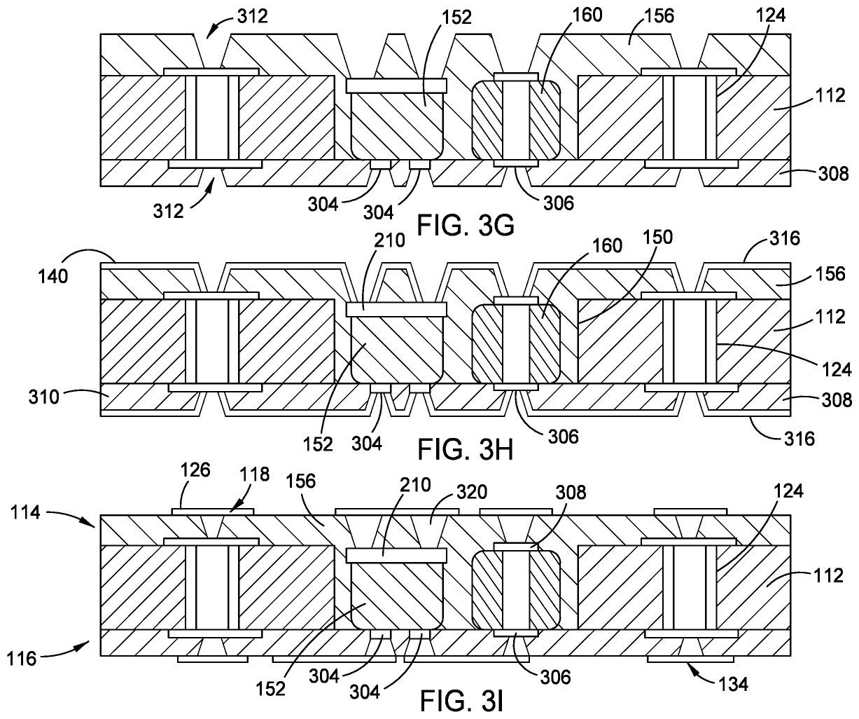

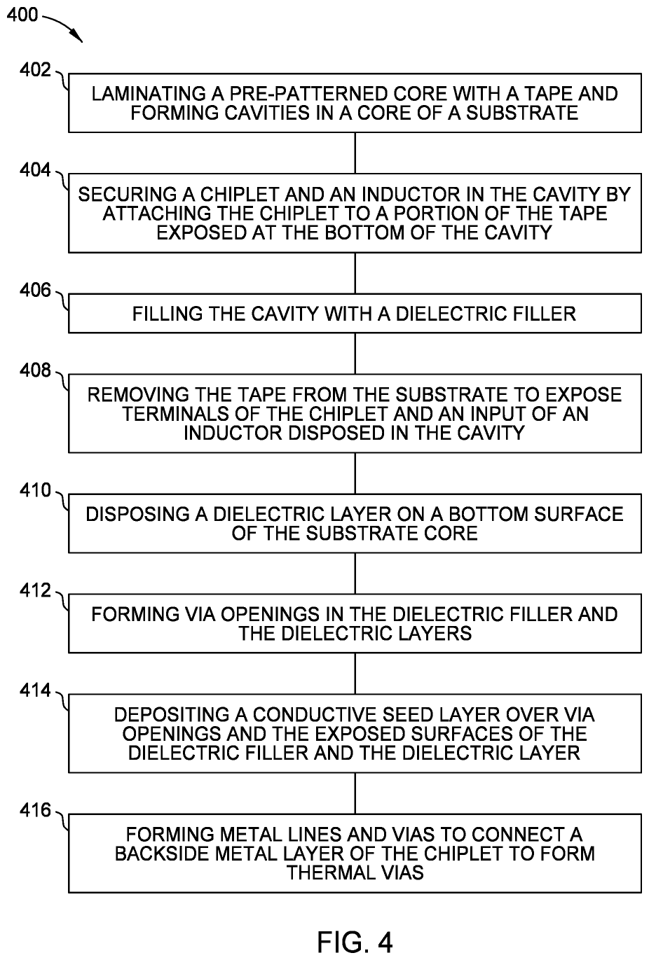

FIGS. 3A-31 depict the substrate 104 used the chip package 100 of FIG. 1 at different stages of a method 400 of fabrication depicted in FIG. 4. The chip package 200 of FIG. 2 may be fabricated similarly, expect that the inductors 160 and the IVR chiplets 152 do not share a common cavity 150 within the core 112 of the substrate 104. The method 400 may be utilized to other substrates for used in chip packages having different configurations.

Operation 402 of the fabrication method 400 begins with a pre-patterned core 112, as shown in FIG. 3A. The pre-patterned core 112 includes the core 112 itself, along with the conductive vias 124 formed therein. The portion of the core 112 over the conductive vias include a pattern metal layer that later will be part of the routing of the upper and lower build-up layers 116.

Operation 402 of the fabrication method 400 continues by laminating the pre-patterned core 112 with a tape 302, such as a die attach tape, as shown in FIG. 3B, and forming cavities 150 in the core 112. The cavities 150 may be formed by drilling, milling, laser ablating or other suitable technique. Although one cavity 150 is shown in FIG. 3B, many cavities are formed in the substrate 104.

The fabrication method 400 continues at operation 404 by securing the IVR chiplet 152 (or other type of chiplet) in the cavity 150 by attaching the IVR chiplet 152 to the portion of the tape 302 exposed at the bottom of the cavity 150, as shown in FIG. 3C. Similarly at operation 404, the inductor 160 is also secured in the cavity 150 by attaching the inductor 160 alongside the chiplet 152 to the tape 302. In FIG. 3C, both the inductor 160 and the IVR chiplet 152 are disposed in the same cavity 150. It is also contemplated, such as when constructing a substrate 104 for use in the chip package 200 illustrated in FIG. 2, that the inductor 160 and the IVR chiplet 152 are disposed in separate cavities 150.

The fabrication method 400 continues at operation 406 as shown in FIG. 3D by filling the cavity with a dielectric filler 156. The dielectric filler 156 also extends over the core 112 of the substrate 104 and the portion of the metal layers exposed on top of the vias 124. The dielectric filler 156 secures the IVR chiplet 152 and inductor 160 in the cavity 150. The fabrication method 400 continues at operation 408 as shown in FIG. 3E by removing the tape 302 from the substrate 104, which exposes the terminals 304 of the IVR chiplet 152 and the input 306 of the inductor 160 disposed in the cavity 150.

The fabrication method 400 continues at operation 410 as shown in FIG. 3F by disposing a dielectric layer 308 on the bottom surface 410 of the substrate core 112. The dielectric layer 308 covers the terminals 404 of the IVR chiplet 152 and the input 406 of the inductor 160 that were formerly covered by the tape 302.

The fabrication method 400 continues at operation 412 with forming via openings 312 in the dielectric filler 156 and the dielectric layer 408, as shown in FIG. 3G. The via openings 312 may be formed by drilling or other suitable technique. The via openings 312 expose the portion of the metal layer formed on the vias 124 on the bottom surface 144 of the substrate 104, and terminals 404 of the IVR chiplet 152, and the input 406 of the inductor 160 on the bottom surface 144 of the substrate 104. The via openings 312 also expose the portion of the metal layer formed on the vias 124 on the top surface 140 of the substrate 104, and the backside metal layer 210 disposed on the IVR chiplet 152, and the output 314 of the inductor 160 exposed on the top surface 140 of the substrate 104.

The fabrication method 400 continues at operation 414 by depositing a conductive seed layer 316 over via openings 312 and the exposed surfaces of the filler 156 and dielectric layers 308, as shown in FIG. 3H. The conductive seed layer 316 contacts the portion of the metal layer formed on the vias 124 on the bottom surface 310 of the substrate 104, the terminals 404 of the IVR chiplet 152, and the input 406 of the inductor 160 exposed through the via openings 312 on the bottom surface 310 of the substrate 104. The conductive seed layer 316 also contacts the portion of the metal layer formed on the vias 124 on the top surface 140 of the substrate 104, backside metal layer 210 disposed on the IVR chiplet 152, and the output 314 of the inductor 160 exposed through the via openings 312 on the top surface 140 of the substrate 104.

After seed layer deposition, lithographic patterning and plating processes are performed at operation 416 to form metal lines and vias, as shown in FIG. 3I. Some of the metal lines and vias contact the backside metal layer 210 of the IVR chiplet 152 to form thermal vias. Some of the other metal lines and vias form the routings 118, 134 of the upper and lower build-up layers 116. At least some of the other metal lines and vias form a routing connecting the output terminal 304 of the IVR chiplet 152 to the input 406 of the inductor 160. At this point, the IC die 102 may be secured to the upper build-up layer 114 at operation 416 to form the chip packages 100, 200 as illustrated in FIGS. 1-2.

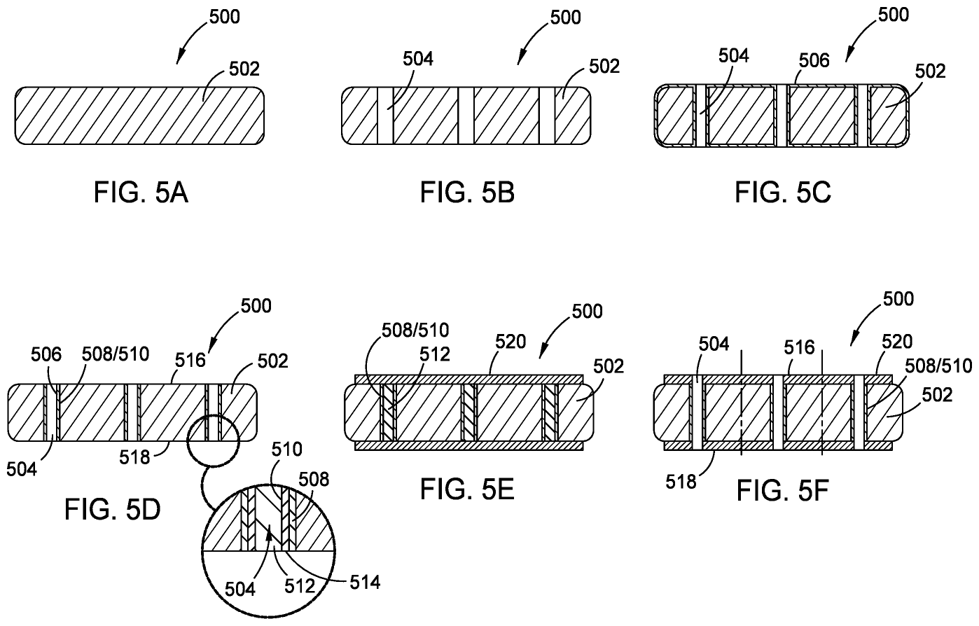

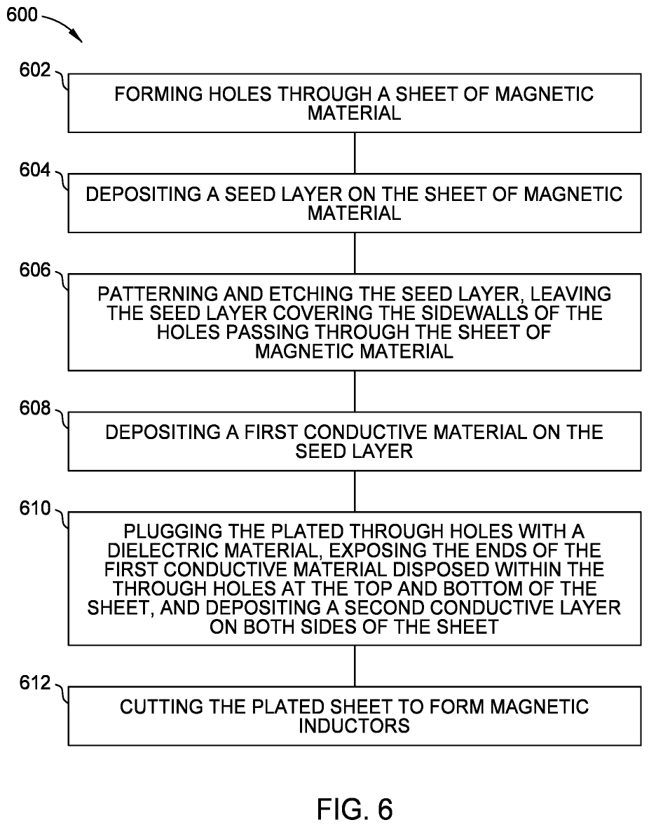

FIGS. 5A-5F depict a magnetic inductor 500 used the chip package 100 of FIG. 1 at different stages of a fabrication method 600 depicted in FIG. 6. The magnetic inductor 500 may be used as the inductor 160 shown in either chip package 100, 200 illustrated of FIGS. 1-2. The inductor 500 fabricated using the method 600 may be utilized to other substrates for used in chip packages having different configurations, or for other desired applications.

The fabrication method 600 of the magnetic inductor 500 starts as shown in FIG. 5A with a sheet 502 of magnetic material. In one example, the magnetic material is a pre-cured ferrite sheet 502, although other magnetic materials may be used. At operation 602, holes 504 are formed through the sheet 502. The holes 504 may be formed by drilling, laser, milling or other suitable technique.

At operation 604, a seed layer 506 is deposited on the sheet 502 of magnetic material, as shown in FIG. 5C. The seed layer 506 also covers the sidewalls 508 of the holes 504 passing through the sheet 502.

At operation 606, the seed layer 506 is patterned and etched, leaving the seed layer 506 covering the sidewalls 508 of the holes 504 passing through the sheet 502. At operation 608, a first conductive material 510 is subsequently deposited on the seed layer 506, as shown in FIG. 5D. In one example, the first conductive material 510 is subsequently plated on the seed layer 506. The first conductive material 510 plated on the seed layer 506 may be copper of other suitable conductive material.

At operation 610, the plated through holes 504 are then plugged with a dielectric material 512. The dielectric material 512 is then ground flat to expose the ends 514 of the first conductive material 510 disposed within the through holes 504 at the top 516 and bottom 518 of the sheet 502. A second conductive layer 520 is then deposited on both sides of the sheet 502. In one example, the second conductive layer 520 is plated on both sides of the sheet 502. The second conductive layers 520 disposed on the top 516 and bottom 518 of the sheet 502 of magnetic material contact the exposed ends 514 of the of the plated conductive material 510 disposed within the through holes 504. Thus, the second conductive layers 520 on the top 516 and bottom 518 of the sheet 502 of magnetic material are electrically connected by the first conductive material 510 disposed within the through holes, as shown in FIG. 5E.

At operation 612. the plated sheet 502 is then cut to form the magnetic inductors 500, with the second conductive layer 520 disposed on the bottom 518 of the sheet 502 of magnetic material forming an input terminal of the inductor 500, the second conductive layer 520 disposed on the top 516 of the sheet 502 of magnetic material forming an output terminal of the inductor, and the input and output terminals connected by the plated hole that is surrounded by the magnetic material, as shown in FIG. 5F. Optionally, the plug may be removed.

Once the inductor 500 is formed, the inductor 500 may be disposed in a substrate as described above with reference to the fabrication method 400 described above, or by a suitable alternative technique.

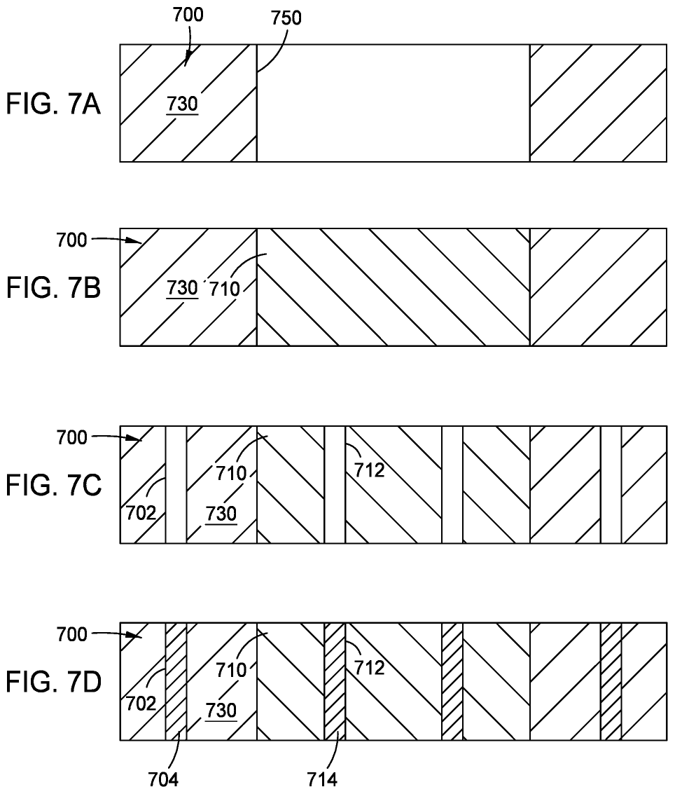

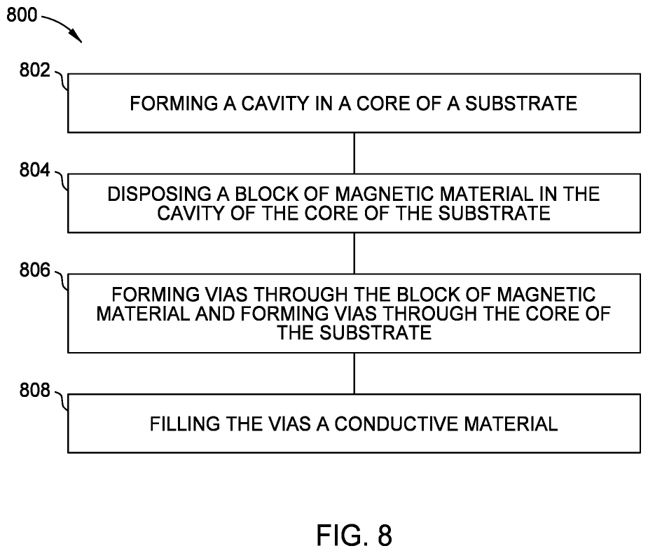

FIGS. 7A-7D depict a substrate 700 having a magnetic inductor 710 that can be used the chip packages 100, 200 of FIGS. 1-2 during different stages of a fabrication method 800 depicted in FIG. 8. The substrate 700 may alternatively be used in other chip packages.

The method 800 being at operation 802 by forming a cavity 750 in a core 730 of a substrate 700, as illustrated in FIG. 7A. The cavity 750 may be formed as described above with reference to the cavity 150. The cavity 750 may also be formed by alternative suitable techniques.

At operation 804, a block 710 of magnetic material is disposed in the cavity 750, as illustrated in FIG. 7B. The block 710 may be secured in the cavity 750 by any suitable technique, for example, using a potting compound.

At operation 806, vias 712 are formed through the block 710 of magnetic material, as illustrated in FIG. 7C. Vias 702 are also formed through the core 730 of the substrate 700. The vias 702, 712 may be formed by drilling or other suitable technique. The vias 702, 712 may be formed at the same time or at different times. The vias 702 are used for routing signal transmission, ground, power through the substrate to the IC die of the chip package.

At operation 808, the vias 702, 712 are filled with a conductive material 704, 714, as illustrated in FIG. 7D. The vias 702, 712 may be filled with the conductive material 704, 714 by plating. A seed layer, not shown, may be disposed between the conductive material 704, 714 and the core 730 and the block 710 of magnetic material. In one example, the conductive material 704, 714 is copper. Alternatively, the conductive material 704, 714 may be another metal suitable for signal and/or power transmission.

After operation 808, a chiplet is similarly secured to the core 730 of the substrate 700, then built-up layers are formed on the core 730 of the substrate 700, for example as described above with reference to FIG. 4. After the built-up layers and routings for formed on the core, the substrate 700 is uses to fabricate a chip package, such as but not limited to the chip packages 100, 200 described above.

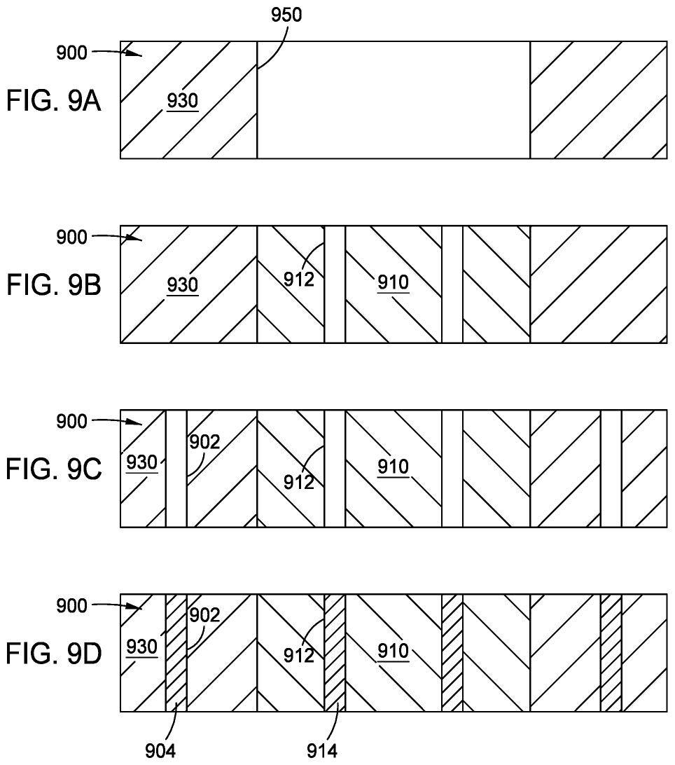

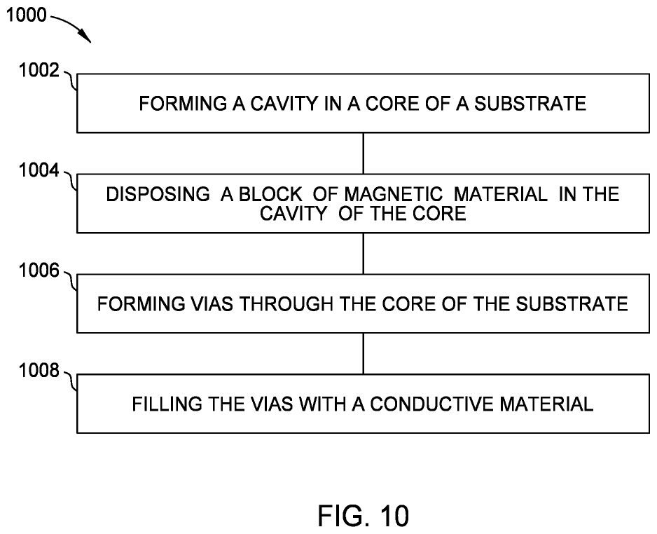

FIGS. 9A-9D depict a substrate 900 having a magnetic inductor 910 that can be used the chip packages 100, 200 of FIGS. 1-2 during different stages of a fabrication method 1000 depicted in FIG. 10. The substrate 900 may alternatively be used in other chip packages.

The method 1000 being at operation 1002 by forming a cavity 950 in a core 930 of a substrate 900, as illustrated in FIG. 9A. The cavity 950 may be formed as described above.

At operation 1004, a block 910 of magnetic material is disposed in the cavity 950, as illustrated in FIG. 9B. The block 910 may be secured in the cavity 950 by any suitable technique, for example, using a potting compound. The block 910 of magnetic material includes preformed vias 912.

At operation 1006, vias 902 are formed through the core 930 of the substrate 900, as illustrated in FIG. 9C. The vias 902 may be formed by drilling or other suitable technique. The vias 902 may be formed before or after the block 910 is secured in the cavity 950 of the core 930 of the substrate 900

At operation 1008, the vias 902, 912 are filled with a conductive material 904, 914, as illustrated in FIG. 9D. The vias 902, 912 may be filled with the conductive material 904, 914 by plating. A seed layer, not shown, may be disposed between the conductive material 904, 914 and the core 930 and the block 910 of magnetic material. In one example, the conductive material 904, 914 is copper. Alternatively, the conductive material 904, 914 may be another metal suitable for signal and/or power transmission.

A chiplet is similarly secured to the core 930 of the substrate 900 prior to, or after then any one or more of the operations 1002, 1004, 1006 and/or 1008. After the chiplet is secured to core 930 of the substrate 900, built-up layers are formed on the core 930 of the substrate 900, for example as described above with reference to FIG. 4. After the built-up layers and routings for formed on the core, the substrate 900 is uses to fabricate a chip package, such as but not limited to the chip packages 100, 200 described above.

While the foregoing is directed to embodiments of the present invention, other and further embodiments of the invention may be devised without departing from the basic scope thereof, and the scope thereof is determined by the claims that follow.

What is claimed is:

1. A chip package comprising:
an integrated circuit (IC) die having functional circuitry;
a substrate having the IC die mounted thereon, the substrate comprising:
a core having at least a first cavity, inductor routing vias, a plurality of signal transmission vias, a plurality of ground routing vias, and a plurality of power routing vias;
an upper build-up layer disposed on the core between the core and IC die, the upper build-up layer including routing coupling the inductor routing vias, the signal transmission vias, and the ground and power routing vias to the functional circuitry of the IC die; and
a lower build-up layer disposed a side of the core opposite the upper build-up layer, the lower build-up layer including routing coupled to the functional circuitry of the IC die through the vias of the core and the routing of upper build-up layer; and
a chiplet disposed in a first cavity formed the core, the chiplet coupled to the functional circuitry of the IC die through upper build-up layer.

2. The chip package of claim 1, wherein the chiplet includes voltage regulator circuitry.

3. The chip package of claim 2 further comprising:
an inductor having an input and an output, the input coupled to an outlet of the voltage regulator circuitry and the output coupled to the functional circuitry of the IC die.

4. The chip package of claim 3, wherein the inductor is coupled to the voltage regulator circuitry through the routing of the lower build-up layer.

5. The chip package of claim 4, wherein the inductor is disposed in the first cavity.

6. The chip package of claim 4, wherein the inductor is disposed in a second cavity formed in the core.

7. The chip package of claim 6, wherein the chiplet further comprises:
a backside metal layer.

8. The chip package of claim 7, wherein the upper build-up layer further comprises:
thermal vias formed on the backside metal layer.

9. The chip package of claim 8 further comprising:
a stiffener disposed on the substrate directly above the thermal vias; and
a lid disposed over the IC die and stiffener, wherein the stiffener and the thermal vias provide a conductive path operable to conduct heat from the backside metal layer to the lid.

10. The chip package of claim 5, wherein the chiplet further comprises:
a backside metal layer.

11. The chip package of claim 10, wherein the upper build-up layer further comprises:
thermal vias formed on the backside metal layer and extending to a top surface of the substrate.

12. The chip package of claim 3, wherein the inductor is an air core inductor formed in the substrate.

13. The chip package of claim 5, wherein the inductor is formed from a magnetic material.

14. The chip package of claim 5, wherein the inductor is a pre-fabricated component and secured in the substrate by a dielectric filler.

15. The chip package of claim 3 further comprising:
a capacitor having one terminal coupled to the both the functional circuitry of the IC die and the output of the inductor.

16. A chip package comprising:
an integrated circuit (IC) die having functional circuitry;
a substrate having the IC die mounted thereon, the substrate comprising:
a core having one or more cavities, a plurality of signal transmission vias, inductor routing vias, a plurality of ground routing vias, and a plurality of power routing vias;
an upper build-up layer disposed on the core between the core and IC die, the upper build-up layer including routing coupling the inductor routing vias, the signal transmission vias, and the ground and power routing vias to the functional circuitry of the IC die; and
a lower build-up layer disposed a side of the core opposite the upper build-up layer, the lower build-up layer including routing coupled to the functional circuitry of the IC die through the vias of the core and the routing of upper build-up layer;
a chiplet disposed in the one or more cavities formed the core, the chiplet having voltage regulating circuitry coupled to the functional circuitry of the IC die through upper build-up layer; and
an inductor disposed in the one or more cavities formed the core, the inductor having an input and an output, the input coupled to an outlet of the voltage regulator circuitry and the output coupled to the functional circuitry of the IC die.

17. The chip package of claim 16, wherein the inductor and the chiplet are disposed in a common cavity of the one or more cavities formed the core.

18. The chip package of claim 17, wherein the common cavity is disposed directly below the IC die.

19. The chip package of claim 16 further comprising:
a stiffener disposed on the substrate directly above a cavity of the one or more cavities in which the chiplet resides;
a backside metal layer formed on the chiplet;
thermal vias formed on the backside metal layer, the thermal via disposed directly below the stiffener; and
a lid disposed over the IC die and stiffener, wherein the stiffener and the thermal vias provide a conductive path operable to conduct heat from the backside metal layer to the lid.

20. A method for fabricating a chip package, comprising:
securing a chiplet and an inductor in a cavity formed in a substrate;
forming build-up layers on the substrate over the chiplet and the inductor, the build-up layers including routing electrically coupled to the chiplet and the inductor; and
mounting an integrated circuit (IC) die on the build-up layers, the IC die including functional circuitry coupled by the routing of the build-up layers to the chiplet and the inductor.
